(19) United States
(12) Patent Application Publication
(10) Pub. No.: US 2011/0270559 A1
(43) Pub. Date: Nov. 3, 2011

(54) IN-SITU REAL-TIME ENERGY STORAGE DEVICE IMPEDANCE IDENTIFICATION

(75) Inventors: Jon P. Christophersen, Idaho Falls, ID (US); John L. Morrison, Butte, MT (US); William H. Morrison, Manchester, CT (US); Chester G. Motloch, Idaho Falls, ID (US)

(73) Assignee: BATTELLE ENERGY ALLIANCE, LLC, Idaho Falls, ID (US)

(21) Appl. No.: 13/100,170

(22) Filed: May 3, 2011

Related U.S. Application Data
(60) Provisional application No. 61/330,766, filed on May 3, 2010.

(51) Int. Cl. G06F 19/00; G01R 27/28; G01R 35/00

(52) U.S. Cl. 702/65; 324/601; 324/649

(57) ABSTRACT

An impedance analysis system for characterizing an energy storage device (ESD) includes a signal vector assembler to generate a signal vector from a composition of one or more waveforms and a signal generator for generating a stimulus signal responsive to the signal vector. A signal measurement device measures a response signal indicative of a response of the ESD substantially simultaneously with when the stimulus signal is applied to the energy storage device. A load variation monitor monitors load variations on the energy storage device due to operational circuitry coupled thereto. An analyzer is operably coupled to the response signal and analyzes the response signal relative to the signal vector to determine an impedance of the energy storage device.

### CROSS-REFERENCE TO RELATED APPLICATIONS

This application claims the benefit of U.S. Provisional Patent Application Ser. No. 61/330,766, filed May 3, 2010, the disclosure of which is hereby incorporated herein in its entirety by this reference.

### STATEMENT REGARDING FEDERALLY SPONSORED RESEARCH OR DEVELOPMENT

This invention was made with government support under Contract No. DE-AC07-05ID14517 awarded by the United States Department of Energy. The government has certain rights in the invention.

### TECHNICAL FIELD

Embodiments of the present disclosure relate generally to determining energy-output device parameters and, more specifically, to determining impedance and output characteristics of energy-storage devices.

### BACKGROUND

The demand for Energy Storage Devices (ESDs) is significantly increasing as more environmentally friendly energy sources are developed and implemented in the field. The United States automotive industry, for example, is seeking to develop plug-in hybrid electric vehicle technologies that can operate a battery in charge depleting mode (i.e., all electric) for up to a 40-mile commute after 15 years of operation. However, energy storage technologies can be very expensive, and the need for accurate state-of-health (SOH) assessment is increasing. Though many SOH assessment techniques have been offered, no industry standard has yet been developed due to the complexity of the problem. Simple passive monitoring of voltage, current, and temperature can yield valuable information about the remaining capacity and energy, but it yields no information about power capability. Power can be determined from resistance, which usually requires charge depleting pulse tests or time consuming electrochemical impedance spectroscopy (EIS) measurements. Neither of these options are suitable for on board, in-situ SOH assessment.

A battery converts stored chemical energy to electrical energy, which may be conveyed as a voltage source. As with any non-ideal voltage source, the battery will have an internal impedance including a combination of resistance and reactance. The internal impedance produces power loss in a system by consuming power as a voltage drop across the source impedance. Ideally, a perfect battery would have no source impedance and deliver any power to the extent of its stored energy, but this is not physically reasonable. Thus, within physical limits, a reduction in source impedance will increase deliverable power.

As a battery ages the internal impedance generally tends to become larger. A brand new battery will have a Beginning Of Life (BOL) impedance much smaller than the End Of Life (EOL) impedance. Similarly, storage capacity of the battery will decrease from BOL to EOL. Therefore, observations of battery parameters such as internal impedance and storage capacity may be used to determine the overall State Of Health (SOH) of a battery. When the internal impedance becomes too large and the battery capacity can no longer reliably deliver energy at the specified power the battery has effectively reached EOL. Furthermore, the rate of change of a battery's internal impedance may be closely related to the state of health of the battery. This is especially true when considering rechargeable or secondary cells. While different secondary battery chemistries undoubtedly perform differently throughout their lives, increases in internal impedance over life at certain frequencies show promise as a uniform method to classify SOH in most chemistries.

Battery impedance also may vary with the relative charge of the battery and temperature. In other words, a battery at half of its rated capacity will have different impedance than a battery at its full rated capacity. Similarly, a battery at different temperatures will exhibit different internal impedance characteristics.

Battery fuel gauges, battery capacity monitors, and battery status monitors attempt to predict battery capacities and give the user an idea of remaining capacity. Conventionally, battery capacity is estimated by current integration, voltage monitoring, or combinations thereof.

Current integration, or coulomb counting as it is commonly called, monitors the battery's available stored charge by measuring the amount of charge that enters and exits the battery through normal cycling. The basis for this approach is, that if all charge and discharge currents are known, the amount of coulometric capacity will be known.

Voltage monitoring methods are based on the recognized relationship between the battery terminal voltage and the remaining capacity. All that is required is voltage measurement of the battery terminals to acquire a rough idea of the State Of Charge (SOC) of the battery.

Both of these methods have limits when applied to actual conditions. Current integration requires a rigorous amount of external current tracking to remain accurate. SOC determination obtained from measurement and integration of external current suffers from errors caused by internal self-discharge currents. If the battery is not used for several days, this self-discharge current dissipates the charge within the battery and can affect the current integration approximation for battery charge.

Voltage monitoring may show errors when measurements are taken with load on the battery. When a load is applied, the voltage drop due to the internal impedance of the battery distorts battery voltage. For many batteries, such as lithium-ion batteries, even after the load is removed, slow time constants and relaxation processes may continue to change the battery voltage for hours. Also, some battery chemistries (e.g., nickel metal-hydride) exhibit a strong voltaic hysteresis, which hinders the possibility of using voltage to track capacity.

Usually, these two methods are combined to operate together under varying conditions. For example, current integration may monitor the SOC while under discharging and charging currents. Whereas, while the battery is at rest voltage monitoring may be employed to monitor self-discharge.

SOC algorithms and measurement techniques are well known, but methods to predict battery life, or state of health (SOH), are less common. As mentioned earlier, SOH is also very dependent on cell impedance. If the cell impedance dependencies on SOC and temperature are known, or closely approximated, it is possible to employ modeling techniques to determine when a discharged voltage threshold will be reached at the currently observed load and temperature. Cell impedance analysis for SOH may be enhanced even more if the battery impedance estimation process were fast enough to eliminate the impedance dependencies on comparatively slow changes like SOC variations and temperature variations. Therefore, a way to monitor battery impedance in-situ at near real time would greatly enhance SOC and SOH predictions due to aging cells.

Conventionally, Electrochemical Impedance Spectroscopy (EIS) is a popular method for analyzing battery impedance. EIS generates a sine excitation waveform at a specific frequency that is applied to the battery. The voltage and current responses are monitored and analyzed to arrive at battery impedance for that particular frequency. Then, the frequency of the sine excitation signal is modified over a range of frequencies to arrive at a frequency spectrum of the battery impedance. This process provides stable, accurate measurements of battery impedance, but is most practical for laboratory conditions, not during in situ operation. In other words, EIS may not work well when the battery is under changing loads as changes imposed upon the sine wave excitation may skew the results. Also, the methodology of the EIS system is inherently serial (i.e., a single frequency for each step), making its application time consuming (often several hours for lower frequency sweeps) and inappropriate for a near real time analysis.

Therefore, to enhance monitoring of life and in-situ charge of a battery or other energy-output device under normal conditions, there is a need for a method and apparatus for determining energy-output device impedance using near real time measurement and analysis that may be employed during in situ operation.

### BRIEF SUMMARY

Embodiments of the present disclosure provide improvements in methods and apparatuses determining energy storage device impedance using near real time measurement and analysis that may be employed during in situ operation.

In accordance with one embodiment of the present disclosure, an impedance analysis system for characterizing an energy storage device includes a signal vector assembler configured to generate a signal vector from a composition of one or more waveforms over a stimulus duration and a signal generator configured for generating a stimulus signal responsive to the signal vector and for switchable coupling to an energy storage device. A response measurement device is operably coupled to the stimulus signal and is configured for measuring a response signal indicative of a response of the energy storage device substantially simultaneously with when the stimulus signal is applied to the energy storage device. A load variation monitor is operably coupled to the energy storage device and is configured for monitoring load variations on the energy storage device due to operational circuitry coupled thereto. An analyzer is operably coupled to the response signal and is configured for analyzing the response signal relative to the signal vector to determine an impedance of the energy storage device.

In accordance with another embodiment of the present disclosure, a method of analyzing an energy storage device includes sampling a direct current value of the energy storage device resulting from operational circuitry coupled thereto. One or more switches are closed after sampling the direct current value to operably couple an impedance analysis system to the energy storage device. A signal vector is formed for analysis of the energy storage device from a composition of one or more waveforms and the signal vector is biased proportional to the direct current value. An impedance analysis is performed by generating a stimulus signal correlated to the signal vector, applying the stimulus signal to a terminal of the energy storage device, sampling a response of the energy storage device to the stimulus signal over a sampling duration, and analyzing the response of the energy storage device relative to the signal vector over the sampling duration to determine an impedance of the energy storage device.

In accordance with a yet another embodiment of the present disclosure, a method of analyzing an energy storage device includes monitoring load variations on the energy storage device resulting from operational circuitry coupled thereto and detecting a condition of interest from the load variations. The method also includes forming a signal vector for analysis of the energy storage device from a composition of one or more waveforms and performing an impedance analysis responsive to detecting the condition of interest. The impedance analysis includes generating a stimulus signal correlated to the signal vector, applying the stimulus signal to a terminal of the energy storage device, sampling a response of the energy storage device to the stimulus signal over a sampling duration, and analyzing the response of the energy storage device relative to the stimulus signal over the sampling duration to determine an impedance of the energy storage device.

### BRIEF DESCRIPTION OF THE DRAWINGS

FIG. 1 is a simplified block diagram of a system for in-situ measurements of energy storage devices according to one or more embodiments of the present disclosure;

FIG. 2 is a simplified software block diagram according to one or more embodiments of the present disclosure;

FIG. 3 is a simplified calibration flow diagram according to one or more embodiments of the present disclosure;

FIGS. 4 and 5 are graphical user interface dialog boxes for interfacing with software and hardware according to one or more embodiments of the present disclosure;

FIG. 6 is a simplified flow diagram for a user directed method of impedance analysis according to one or more embodiments of the present disclosure;

FIG. 7 is a simplified hardware diagram of components for pulse and voltage detection according to one or more embodiments of the present disclosure;

FIG. 8 is a graphical user interface dialog boxes for defining trigger parameters according to one or more embodiments of the present disclosure;

FIG. 9 is a simplified flow diagram showing automated impedance measurements according to one or more embodiments of the present disclosure; and

FIG. 10 is a simplified flow diagram of hardware control according to one or more embodiments of the present disclosure.

### DETAILED DESCRIPTION

In the following description, reference is made to the accompanying drawings which form a part hereof, and in which is shown, by way of illustration, specific embodiments in which the disclosure may be practiced. The embodiments are intended to describe aspects of the disclosure in sufficient detail to enable those skilled in the art to practice the invention. Other embodiments may be utilized and changes may be made without departing from the scope of the disclosure. The following detailed description is not to be taken in a limiting sense, and the scope of the present invention is defined only by the appended claims.

Furthermore, specific implementations shown and described are only examples and should not be construed as the only way to implement the present disclosure unless specified otherwise herein. It will be readily apparent to one of ordinary skill in the art that the various embodiments of the present disclosure may be practiced by numerous other partitioning solutions.

In the following description, elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the embodiments disclosed herein may be implemented or performed with a general purpose processor, a special purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

Also, it is noted that the embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a function, a procedure, a subroutine, a subprogram, etc. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

It should be understood that any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise a set of elements may comprise one or more elements.

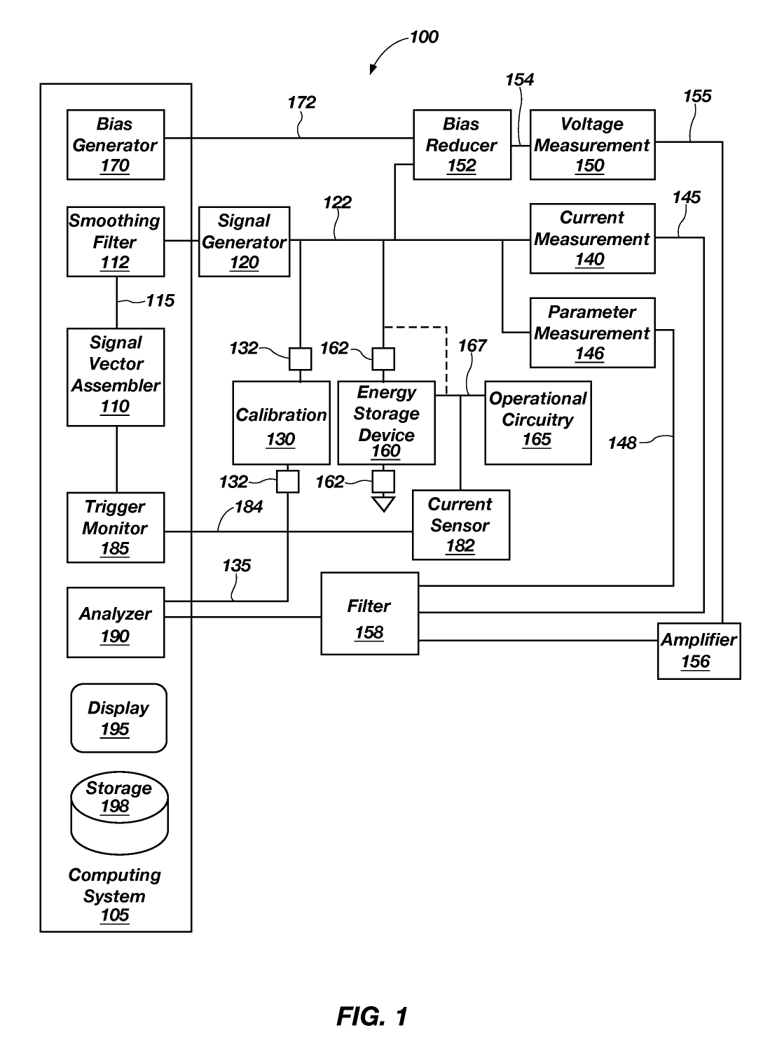

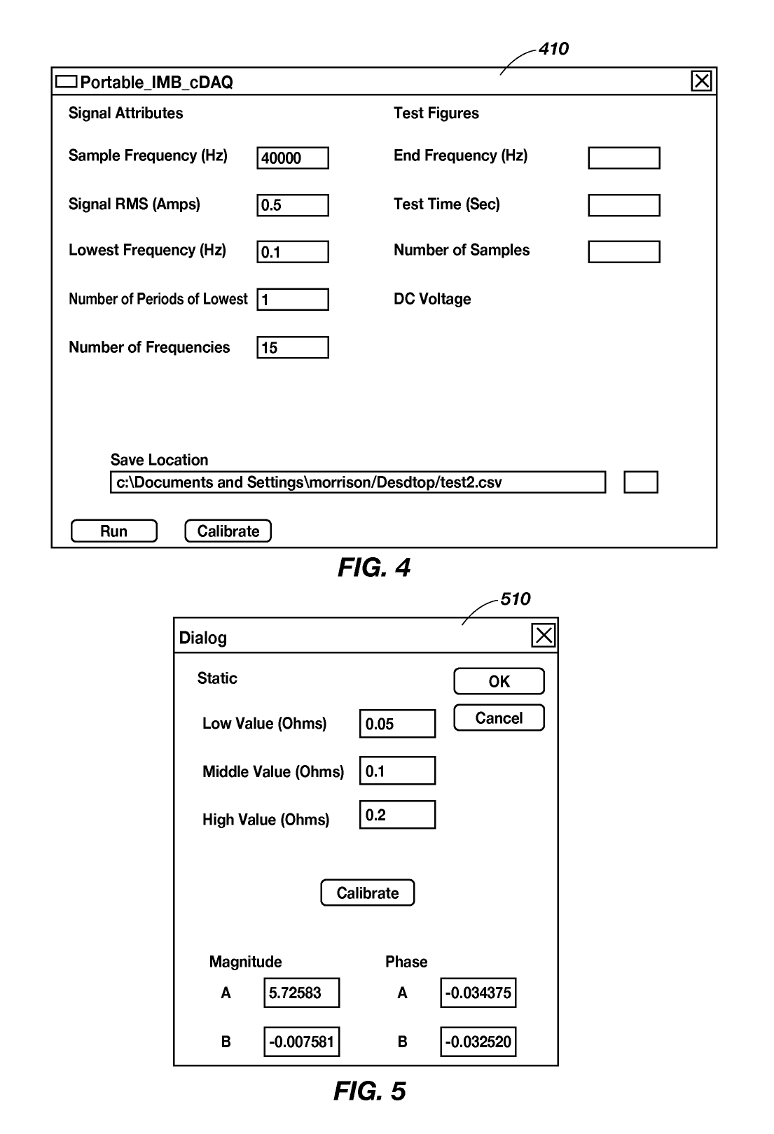

Elements described herein may include multiple instances of the same element. These elements may be generically indicated by a numerical designator (e.g., 110) and specifically indicated by the numerical indicator followed by an alphabetic designator (e.g., 110A) or a numeric indicator preceded by a “dash” (e.g., 110-1). For ease of following the description, for the most part element number indicators begin with the number of the drawing on which the elements are introduced or most fully discussed. Thus, for example, element identifiers on a FIG. 1 will be mostly in the numerical format 1xx and elements on a FIG. 4 will be mostly in the numerical format 4xx.

Embodiments of the present disclosure provide improvements in methods and apparatuses determining energy storage device impedance using near real time measurement and analysis that may be employed during in situ operation.

For ease of description, the terms “battery” and “energy storage device” (ESD) are used interchangeably herein and refer to any type of electrochemical energy storage device suitable for impedance measurements thereof.

The present disclosure involves an impedance analysis system including battery interface hardware (also referred to herein as an Impedance Measurement Box (IMB)) and control software. The impedance analysis system may be configured to apply one or more stimulus signals to a battery. The stimulus signals are generally configured as low-level, charge neutral signals and the impedance analysis system may be configured to automatically calculate impedance spectra under both no-load conditions and load conditions on the battery.

The stimulus signals can be of any suitable waveform and frequency that can yield impedance information about the battery. As non-limiting examples, some possible stimulus signal generators are discussed below.

One such method is known as “Fast Summation Transformation (FST)” as described in U.S. patent application Ser. No. 12/217,013 to Morrison et al., the contents of which is hereby incorporated by reference in its entirety. The FST measurement uses a bandwidth limited octave harmonic sum-of-sines signal that is injected into the battery. For each frequency of interest, an output response is rectified relative to the sine and cosine, with the samples added and normalized to a number of periods. An impedance spectrum is then determined with a simple linear algorithm that solves for the real and complex response.

Other exemplary methods of generating test signals include; Impedance Noise Identification (INI) as described in U.S. Pat. No. 7,675,293, Compensated Synchronous Detection (CSD) as described in U.S. Pat. No. 7,675,293, Reduced Time FST (RTFST) as described in U.S. patent application Ser. No. 12/772,880. The contents of each of these references is hereby incorporated by reference in their entirety.

FIG. 1 is a simplified block diagram of a system for in-situ measurements of batteries according to one or more embodiments of the present disclosure. FIG. 1 illustrates an impedance analysis system 100 for characterizing an energy storage device 160 according to the present invention. The impedance analysis system 100 includes a signal vector assembler 110 for generating a signal vector 115 and may also include a smoothing filter 112 for smoothing and modifying the signal vector 115. The signal vector 115 is a time varying signal, which may include signal vectors of the type described above. For application to an energy storage device 160, a signal generator 120 converts the signal vector 115 to a stimulus signal 122, which may be configured as a current source signal or a voltage source signal suitable for application to a terminal of the energy storage device 160. The energy storage device 160 generally may be connected to the stimulus signal 122 and the other terminal may be coupled to a ground.

The energy storage device 160 may be coupled to operational circuitry 165 via connection 167. The operational circuitry 165 represents any loads configured to be driven by the battery 160, which may discharge the battery 160, as well as any charging circuitry for restoring charge to the battery 160. The impedance analysis system 100 may be configured for in-situ operation. As such, the stimulus signal 122 may be coupled to the energy storage device for performing impedance analysis during normal operation of the operational circuitry 165.

A bias generator 170 may be included to generate a bias signal 172, which approximates the present voltage on the energy storage device 160. A bias reducer 152 may be included to compare the voltage at the energy storage device 160 to the bias signal 172 to obtain a difference between the two signals, which represents a bias-reduced response 154 to the stimulus signal 122. A voltage measurement device 150 may be coupled to the energy storage device 160 (connection not shown), or the bias-reduced response 154 to determine the voltage of the energy storage device 160.

In some systems, according to the present disclosure, the bias generator 170, signal vector assembler 110, filter 112, a trigger monitor 185, and an analyzer 190 may be discrete elements targeted at their specific function. However, in other systems according to the present disclosure, these functions may be included in a computing system 105. Thus, the computing system 105 may include software for performing the functions of assembling signal vectors, digital filtering, averaging the sampled voltage of the energy storage device 160 to generate the bias signal 172, and analyzing various input signals relative to the signal vector to determine impedance of the energy storage device 160. In still other systems, some of these functions may be performed with dedicated hardware and others may be performed with software.

In addition, the computing system 105 may include a display 195 for presenting control selection operations and data in a format useful for interpreting impedance characteristics of the energy storage device, as is explained more fully below. The display may also be used for presenting more general battery characteristics of interest, such as, for example, SOH or SOC. The computing system 105 may also include storage 198 for storing sampled information from any of the processes described below as well as for containing computing instructions for execution by the analyzer 190 to carry out the processes described below.

The signal vector assembler 110 may be any suitable apparatus or software for generating the signal vector 115 with an average amplitude substantially near zero. The signal vector assembler 110 may be configured as digital logic or as computer instructions for execution on the computing system 105. The smoothing filter 112 may be a bandpass filter used for smoothing the signal vector 115 by removing high frequencies and low frequencies to present an analog signal more suitable for application to the energy storage device 160. The smoothing filter 112 may include a digital filter configured as digital logic or as computer instruction for execution on the computing system 105. The smoothing filter 112 also may include an analog filter configured as analog elements. Finally, the smoothing filter 112 may include a digital filter and an analog filter in combination.

For example, a digital smoothing filter may bandwidth limit a random noise signal as the signal vector 115 and smooth transitions between the random data points. The digitally filtered random noise may then be filtered with analog elements to limit the bandwidth to be less than the Nyquist frequency of the sample rate for the analyzer 190.

The stimulus signal 122 may be applied to the energy storage device 160 in-situ during normal operation or possibly during other testing operations. For the in-situ application, the stimulus signal 122 should keep the energy storage device 160 substantially charge neutral. In other words, the stimulus signal 122 should have an average current substantially near zero. Therefore, the signal generator 120 may be configured to be voltage controlled, while keeping the energy storage device 160 charge neutral relative to the absence of the stimulus signal 122, and be transparent to the rest of the energy storage device system when not in use.

The actual current at the energy storage device 160 as a result of the stimulus signal 122 may be determined by a current measurement device 140 coupled to the stimulus signal 122 and configured to generate a measured current response 145.

Depending on the system and energy storage device 160, in some embodiments, it may be better to sample the response as a voltage, while in other embodiments, it may be better to sample the response as a current. Therefore, the current measurement device 140 and the voltage measurement device 150 may be referred to herein generically as a signal measurement device.

As mentioned earlier, for measuring the response of the energy storage device 160 to the stimulus signal 122, the bias reducer 130 may be coupled to the stimulus signal 122 and configured to generate a bias-reduced response 154. Since the energy storage device 160 is generally holding a charge while impedance data are gathered, a large bias voltage may be constantly present within all the voltage measurements. Thus, measuring the large voltage of the energy storage device 160 may require a large dynamic range on the order of many volts, whereas measuring the voltage response to the stimulus signal 122 may require sampling small changes on the order of micro-volts. A measurement system having the dynamic range necessary to measure the DC offset of the energy storage device 160 may not have the precision to measure the small variations in the voltage response.

Thus, the bias reducer 130 effectively subtracts the DC voltage offset from the voltage at the energy storage device 160 leaving the bias-reduced response 154, which substantially represents only the response of the energy storage device 160 to the stimulus signal 122.

A parameter measurement module 146 may be included for measuring and reporting to the analyzer 190 additional parameters of interest in systems with an energy storage device 160, such as, for example, state of charge, temperature, and indications of a discharging or charging state. This information may be sent to the analyzer 190 as a parameter signal 148.

A measured voltage response 155, whether direct or bias-reduced, the measured current response 145, and the parameter signal 148 may be operably coupled to the analyzer 190. The analyzer 190 is configured for periodically sampling signals that may be analog input signals (e.g., 145, 155, and 148) and converting them to digital data to create records of a time-varying voltage response, a time-varying ESD voltage (i.e., the voltage of the ESD with no stimulus applied), or a combination thereof. The time-varying voltage response may be used by the analyzer 190 for determining impedance characteristics of the energy storage device, as is discussed more fully below. The time-varying ESD voltage may also be used by the bias generator 170 for creating the bias signal 172.

The input signals (145, 155, and 148) may include a relatively small range of values. Thus to condition the input signals (145, 155, and 148) for sampling by the analyzer 190, it may be desirable to amplify the input signals with an optional amplifier 156. Furthermore, it may be desirable to filter the input signals with an optional filter 158. Filtering may be useful to remove noise (e.g., unwanted instrumentation noise, as opposed to the desired stimulus signal 122). Filtering also may be useful for anti-aliasing to remove high frequencies above the Nyquist frequency relative to the sampling rate of the analyzer 190.

The connections of the amplifier 156 and filter 158 shown in FIG. 1 are examples of one implementation. Any other connection for conditioning the input signals before sampling by the analyzer 190 are contemplated as within the scope of the present disclosure.

One or more switches 162 may be included to allow for selective coupling and decoupling of the energy storage device 160 from the battery interface hardware. The energy storage device 160 is normally connected to the operational circuitry 165 as illustrated by signal 167. In some embodiments, the stimulus signal 122 may be coupled directly to signal 167 or indirectly through switch 162.

Some embodiments may include a calibration module 130. The calibration module may include one or more switches 132 to selectively couple it to the stimulus signal 122 and a calibration response signal 135. While not shown, a person of ordinary skill in the art will recognize that the calibration response signal 135 may also be conditioned through one or more of the amplifier 156 and the filter 158. The calibration module 130 may be stimulated in a manner similar to the way the energy storage device 160 will be stimulated during an impedance analysis. In other words, the same signal vector may be applied to the calibration module 130 as is to be applied to the energy storage device 160. As a result, with a baseline operation defined with known values of impedance from the calibration module 130, the analyzer can compensate for any system induced changes, such as for example, noise due to circuits and connections in the system and temperature of the system. As one example, the calibration module may include a variable shunt, with selectable impedance values to perform the calibration at various impedance values.

The switches 162 and 132 may be manually controlled or may be electrically controlled by the analyzer 190 and may be any suitable switch such as, for example, Field Effect Transistors (FETs) and relays.

Some embodiments may include a current sensor 182 watching a load variation on signal 167 to generate a load variation signal 184. The trigger monitor 185 senses the load variation signal 184. The current sensor 182 and the trigger monitor 185 may be collectively referred to herein as a load variation monitor. The load variation monitor examines changes in the form of current between the operational circuitry 165 and the energy storage device 160. Thus, the impedance analysis system 100 may be automatically triggered to perform impedance analysis operations in response to conditions of interest occurring during operation of the operational circuitry 165. Such conditions may be, for example, specific levels of charging, specific levels of discharging, anomalous pulses, expected pulses, and combinations thereof, as explained more fully below.

Thus, the impedance analysis system 100 may be fully automated, as part of an overall diagnostic system (e.g., a battery management system), may include a user interface for manual control applications, and may include both automated control and manual control. In many circumstances, it may be advantageous to have an automated control system that also accepts manual user input when required (e.g., automatic onboard vehicle diagnostics with periodic user updates during regular automotive maintenance service).

Once triggered, the control software instructs the battery interface hardware to inject a current signal into the energy storage device 160 and sense the response of the energy storage device 160. From the collected data, the control software may then calculate impedance spectra, archive the impedance spectra in the storage 198 for diagnostic applications displays information about the impedance spectra on the display 195 for a user, and combinations thereof.

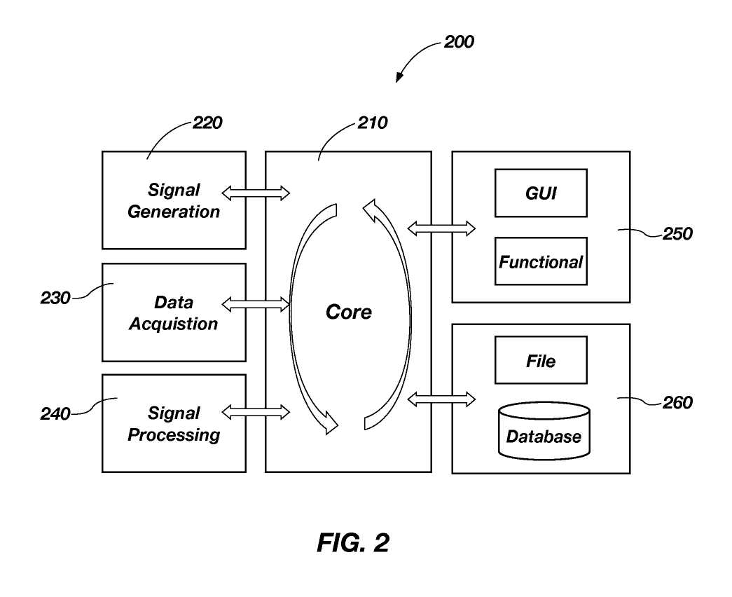

FIG. 2 is a simplified software block diagram according to one or more embodiments of the present disclosure. Referring to FIGS. 1 and 2, the control software 200 can be implemented under both no-load and load conditions. Impedance measurements under no-load conditions would occur when the energy storage device 160 is at open-circuit voltage. For load measurements (e.g., during cycling), the control software can be triggered once the impedance analysis system 100 detects particular pulses or other characteristics from the current sensor.

The control software 200 may be configured to provide a user friendly interface 250 in the form of functional controls and a Graphical User Interface (GUI) to enable control and operation of performing in-situ impedance measurements on the energy storage device 160 under load or no load conditions. As a non-limiting example, the software architecture may be based around a central core 210 responsible for the software execution and sequencing. The central core 210 may be written in a programming language (e.g., C) such that it can be distributed to multiple target platforms with minimal changes. When activated, the central core 210 may trigger a signal generator 220 to inject the stimulus signal 122 into the energy storage device 160. The response may then be measured through a data acquisition block 230. Both the input and response may then be used to determine system impedance with a signal processing block 240. The central core 210 may then display information related to the impedance to a user through the GUI 250 and store the results in a database 260 for future use (e.g., state-of-health prognostic assessment).

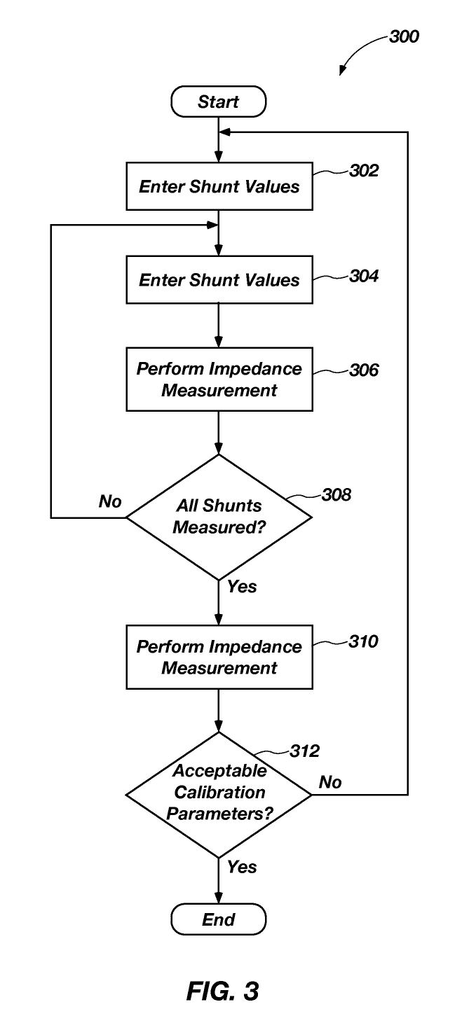

FIG. 3 is a simplified calibration flow diagram according to one or more embodiments of the present disclosure. Prior to use, it may be desirable to calibrate the impedance analysis system 100. In one embodiment, the calibration data processing may be based upon a least squares regression analysis. The calibration software may be preloaded with some initial calibration constants that will be updated each time a calibration is performed. One embodiment of a calibration flow diagram is shown in FIG. 3.

FIGS. 4 and 5 are graphical user interface dialog boxes for interfacing with software and hardware according to one or more embodiments of the present disclosure. As shown in FIG. 4, an operator may select “Calibrate” from a control dialog box 410 to update the system to bring up a calibrate dialog box 510 shown in FIG. 5. In the embodiment of FIG. 5, three shunt values are presented as resistance type impedances. As shown, the values for the three shunts may include default values of 50, 100, and 200 milliohms, but the inputs can be modified by the user for different impedance values if desired.

A calibration process 300 may begin with an operator establishing system connection (e.g., laptop USB hook-up to the IMB, IMB plug in and power on). At operation block 302, the operator starts the IMB system software and in the control dialog box 410 selects “Calibrate.”

The impedance analysis system 100 opens the calibrate dialog box 510 as shown in FIG. 5 and the existing calibration constants are displayed. Operation block 304 indicates that the operator may adjust the shunt values. If the user clicks on “OK,” the calibration dialog box 510 will close and the control dialog box 410 of FIG. 4 will reopen to enable the user to “Run” an impedance analysis.

As indicated by operation block 304, if the user clicks on “Calibrate” in the calibrate dialog box 510, a message will pop up and direct the user to hook up the low value shunt. The operator does that, clicks the “OK” button and then the message goes away.

Operation block 306 indicates the impedance analysis is performed on the calibration module 130 (FIG. 1) using the low shunt value.

Decision block 308 tests to see if impedance analysis has been performed for all shunt values. If not, control passes back to operation block 304, where a new message to the user appears directing the user to hook up the middle value shunt, or the high value shunt. The operator does that, clicks the “OK” button and then the message goes away. The impedance analysis is then repeated.

If all shunt values have been analyzed, operation block 310 indicates that the impedance analysis system 100 determines the baseline operation parameters based on a combination of the impedance analyses at each of the shunt values. As a non-limiting example, this determination may include a least squares fit between the various shunt analyses and a least squares fit to signal vector preset phase shift detected for each frequency response for a given shunt value. One example of resulting magnitude and phase parameters determined from the least squares fit are shown at the bottom of the calibrate dialog box 510.

Decision block 312 indicates that the operator may decide to run the calibration operation again, if desired. If so, control passes back to operation block 302. If not, the calibration process 300 is complete.

When the calibration process 300 is complete, a new message to the operator appears telling the operator that the system is calibrated and the system displays updated calibration constants. When the user clicks the “OK” button, the system accepts the new calibration and the control dialog box 410 returns.

With the calibration process complete, the user would now click “run” in the control dialog box 410 to perform a test, change the test conditions, or “Exit” to close the program.

As one example of parameters used to generate a signal vector 115 (FIG. 1), the control dialog box 410 shows various parameters that may be set for a sum-of-sines (SOS) type signal vector 115 (FIG. 1), such as, for example from the FST algorithm.

After calibration, or to run the impedance analysis system 100 without calibration, the operator may perform the following operations.

1. The operator establishes system connection (e.g., laptop USB hook-up to the IMB, IMB plug in and power on).

2. The user starts the IMB system software and in the control dialog box 410, the user can change default settings and observe control parameters as per Table 1 below. These control parameters may be saved until the program is closed and then may revert back to default values when the program is restarted. When the user clicks “Run,” the system software performs a battery impedance measurement and writes the results to a data output file. If the user clicks “Run” again, the “as set” parameters will be used and the test will run again.

TABLE 1
User Directed Measurement Graphical
User Interface Data Input and Display

| | | DEFAULT | |
|---|---|---|---|
| USER INPUTS | | VALUE | |
| Sample Frequency: | DAQ sample rate for D/A and A/D | 40 | kHz |
| RMS Current: | Total SOS RMS current during | 0.5 | A. RMS |
| | excitation time | | |
| Lowest Frequency: | Lowest frequency in SOS | 0.1 | Hz |
| Number of periods: | Duration of SOS in periods of | 1.0 | |
| | lowest freq. | | |
| Number of frequencies: | Number of frequencies in SOS | 15 | |

| | |
|---|---|
| Save Location: | Name and path for output file |

SYSTEM PARAMETERS DISPLAYED

| | |
|---|---|
| End frequency: | The highest frequency in SOS |
| Test time: | The time duration of SOS |
| Number of samples: | Total number of samples in SOS |
| DC Voltage: | The system measurement of test ESD |
| | voltage prior to start of test |

In one embodiment, the signal generation block 220 (FIG. 2) may create an octave harmonic sum-of-sines signal and the corresponding Fast Summation Transformation (FST) analysis technique. The impedance measurement event can be generated in at least two different methods. In one embodiment, the system performs a user directed measurement and determines the impedance. In another embodiment, the control software is programmed to operate in an autonomous mode and inject the electrochemical ESD with an input signal once it is triggered by some event the system observes while monitoring the ESD (e.g., a voltage jump when under load).

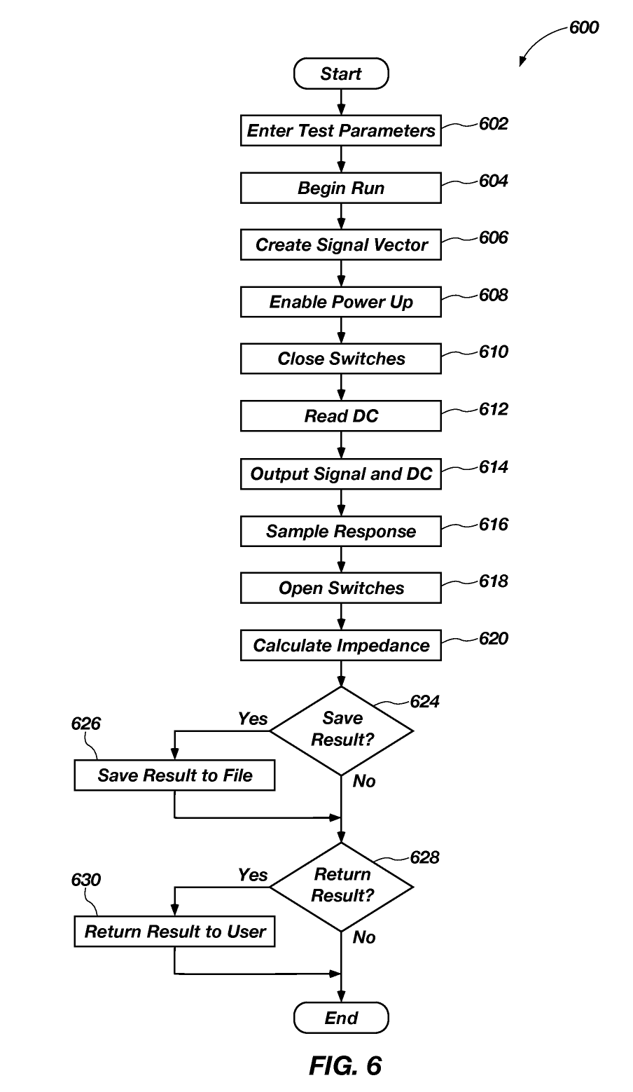

FIG. 6 is a simplified flow diagram for a user directed method 600 of impedance analysis according to one or more embodiments of the present disclosure. When discussing the user directed method 600, reference will be made to FIGS. 6, 1, and 2. When initiated, the software performs any necessary initialization functions such as; loading persistent test parameters, allocating memory, verifying that the necessary modules are available, verifying that a data acquisition system (DAQ) is available, etc. This initialization process may occur at the initial program startup and need only be performed once, not every time a test is performed.

The control dialog box 410 that might implement the User Directed Method (UDM) is shown in FIG. 4.

As indicated by operation block 602, within the control dialog box 410, a user would review and change the default settings, if so desired, of the test conditions illustrated in the control dialog box 410. Table 1 summarizes some possible data inputs and data displayed in control dialog box 410.

Operation block 604 indicates that the user has selected “Run” from the control dialog box 410 to begin the impedance analysis, which begins with information in the form of input parameters to perform the test. These input parameters consist of data such as the number of frequencies, start frequency, stop frequency, desired RMS current, etc. The impedance analysis is capable of performing multiple types of tests and is not dependent on a specific test structure.

Operation block 606 indicates that the signal vector is generated by the signal generation module 220. The parameters acquired from the program interface module contain the necessary parameters and are passed to the signal generation module. The signal generation module 220 then returns the appropriate signal to the program core 210.

Operation blocks 608 and 610 indicate that the software directs the DAQ to issue the digital signal that closes the relay to power up the IMB and close the switches 162 to connect the impedance analysis system 100 to the energy storage device 160.

Operation block 612 indicates that a measurement of the Direct Current (DC) voltage of the energy storage device 160 may be sampled prior to a test. This measurement may be averaged and is output to the bias reducer 152 as the bias signal 172 prior to initiating the impedance analysis.

Operation block 614 indicates that the bias signal 172 and the signal vector 115 are output to the bias reducer 152 and the signal generator 120, respectively to perform the impedance analysis. Operation block 616 indicates that the analyzer 190 samples the measured voltage response 155 to create a time-varying voltage response for analysis.

Operation block 618 indicates that the switches 162 may now be opened to disconnect the impedance analysis system 100 from the energy storage device 160.

Operation block 620 indicates that the signal processing module 240 calculates impedance responsive to the signal vector 115 and the time-varying voltage response. Information about the energy storage device 160, such as, for example, a battery internal impedance spectrum may be derived.

Decision block 624 tests to see if the user desires to have the present analysis stored to a file. If so, operation block 626 indicates that the data is stored to a file.

Decision block 628 tests to see if the user desires to have the present analysis presented on the display 195. If so, operation block 630 indicates that the data is presented to the user.

Following this sequence, the program core 210 then may perform any necessary test cleanup, such as freeing temporary variables. After this step, the program core is ready to receive a “Start Test” call and perform another test. If no more tests are desired, the user exits the program and the interface module 250 notifies the program core 210. The program core 210 then performs all cleanup operations such as freeing persistent data, writing any desired performance variables to the system file, closing all libraries and then returning, thus, ending the session.

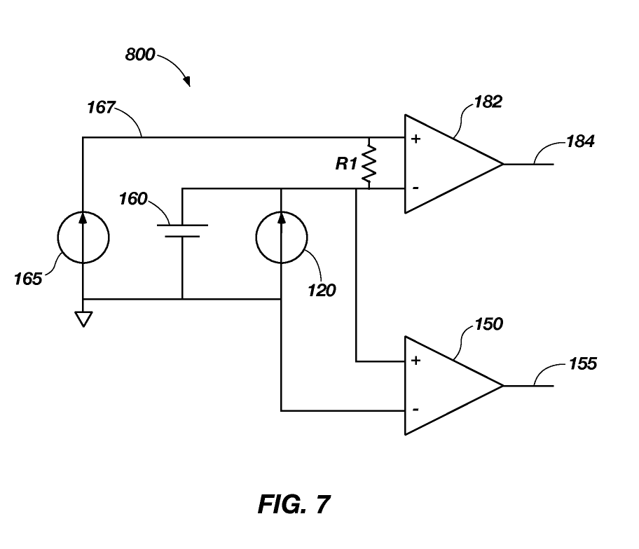

FIG. 7 is a simplified hardware diagram of components for pulse and voltage detection according to one or more embodiments of the present disclosure. This diagram illustrates one particular implementation for some of the functional blocks illustrated in FIG. 1 and like functions use the same element identifiers. The operational circuitry 165 is illustrated as a current source coupled to signal 167, which is coupled to the energy storage device 160 through a shunt resistor R1. The signal generator 120 is also illustrated as a current source coupled to the energy storage device 160.

Differential amplifier 182 is configured to amplify a voltage drop across shunt resistor R1 and, therefore, gives a voltage signal (i.e., the load variation signal 184) indicative of the current being drawn from, or injected in, the energy storage device 160.

Another differential amplifier 150 acts as the voltage measurement device 150 (as shown in FIG. 1), to amplify or buffer the voltage across the energy storage device 160. The trigger monitor 185 samples the load variation signal 184 and system software examines the load variation to determine if a condition of interest has occurred. If a condition of interest is detected, then a preconfigured impedance analysis is triggered and an impedance spectrum of the energy storage device 160 under load is obtained. System software can be configured to detect a wide variety of load variations and then trigger the appropriate predetermined impedance analysis for that load variation to obtain the desired impedance measurement. These in-situ impedance measurements under load provide useful data when assessing state-of-health and remaining useful life of the energy storage device 160.

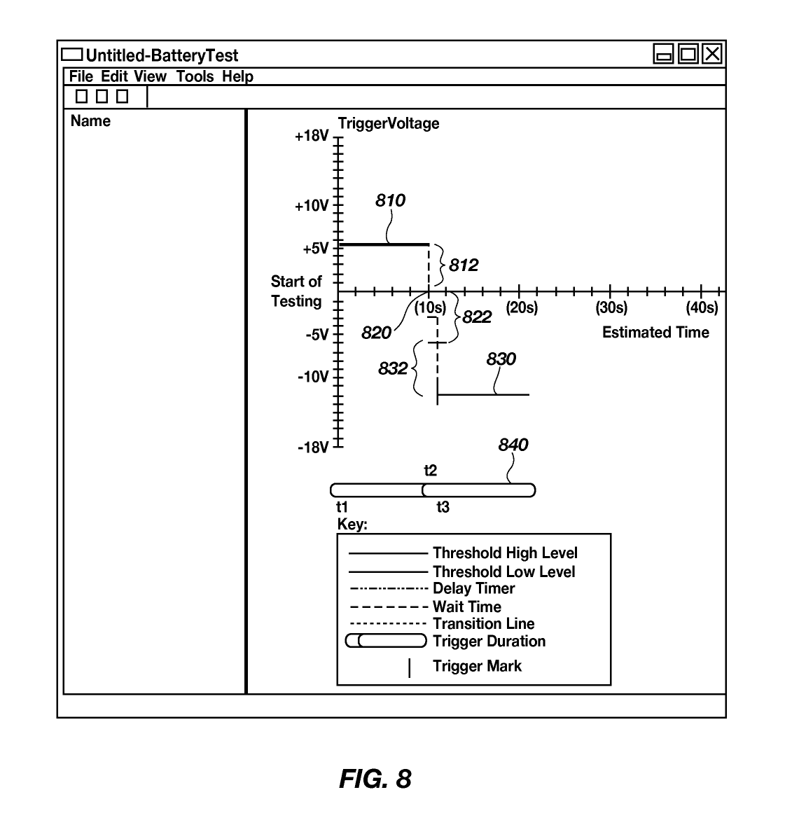

FIG. 8 is a graphical user interface dialog boxes for defining trigger parameters according to one or more embodiments of the present disclosure.

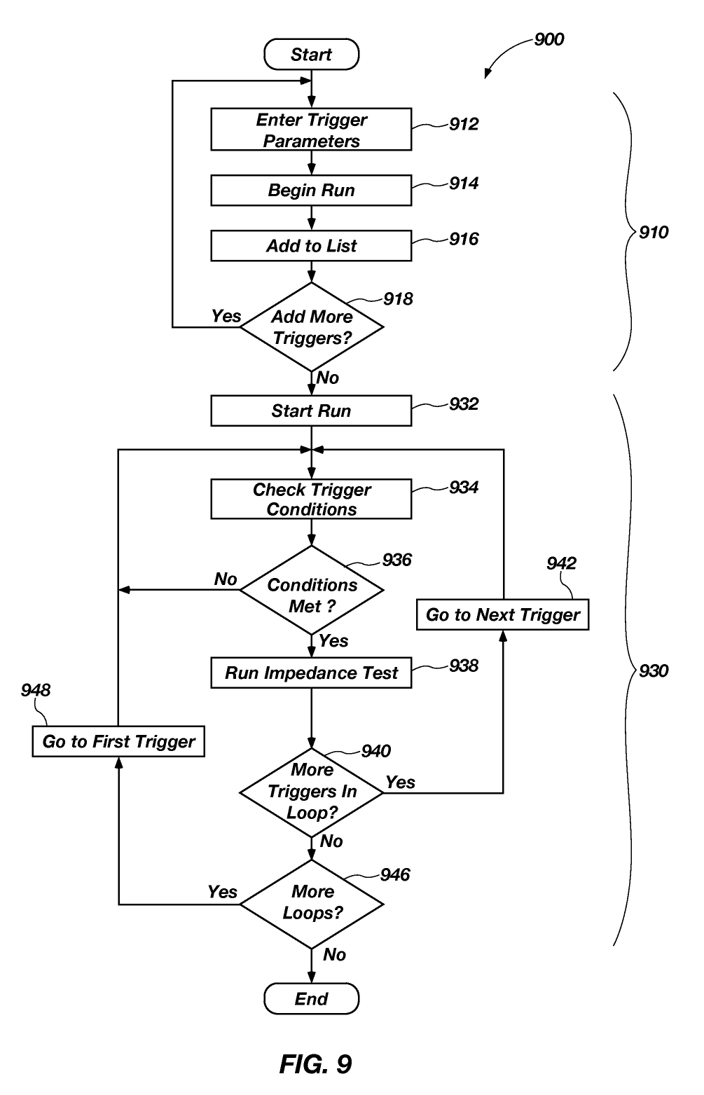

FIG. 9 is a simplified flow diagram showing automated impedance measurements according to one or more embodiments of the present disclosure. FIGS. 8 and 9 will be discussed together with reference to FIGS. 1 and 2 when appropriate. In an automated, triggered system, a series of impedance measurements can be automated based on triggering the control software to execute an impedance analysis based on a predetermined pattern of voltage pulses, voltage levels, current levels, or other conditions of interest at the energy storage device 160. A user may design a test sequence by stringing together these triggers. When executed, the software system monitors the trigger signal and responds by automatically performing the appropriate tests when the trigger conditions are satisfied. FIG. 8 shows a representative GUI that displays a triggered profile. In this example, there are three different trigger markers (t1, t2, and t3), which are also indicated by identifiers 810, 820, and 830, respectively. Tolerance spreads for each of the different trigger markers are also indicated by identifiers 812, 822, and 832 for trigger markers t1, t2, and t3, respectively. The first triggered measurement 810 occurs when the software detects a voltage of about 5.5±2.5 V. The next measurement 820 will then be triggered once the voltage reads about −1.5±1.5 V. The third and final trigger 830 initiates a measurement when the voltage is between about −12±6 V. The trigger marker, threshold levels, delay times and wait times can be adjusted by the user. Trigger line 840 indicates each of the trigger parameters in a single line.

FIG. 9 gives a flow diagram for an automated process 900. The automated process comprises a test sequence. A test sequence is made up of either a set number or a continuous sequence of test loops. Each test loop has a finite number of triggers with attached tests. When executed, each trigger will execute and then wait for the next trigger in the test loop. At the end of the test loop, the trigger sequence is reset and executed again. This continues for the selected number of test loops.

Group 910 indicates operations and decisions to be performed by the user to set up the automated process. Group 930 indicates operations and decisions to be performed during the automated process.

Operation blocks 912 and 914 indicates that the user designs a test sequence by entering trigger parameters and test parameters, such as, for example, using the GUI illustrated in FIG. 8.

Operation block 916 indicates that the designed test sequence is added to a list of test loops. Decision block 918 determines if the user wants to design more test sequences. If so, control transfers back to operation block 912. If not, control transfers to the automated process, indicated by Operation block 932 to start the automated run. While not shown, the user may set other parameters for the test sequence, such as, for example, how many times the test loop executes and the location of the results file.

Operation block 934 and decision block 936 indicate that the process executes a loop until a desired trigger condition is met. When a trigger condition is met, operation block 938 indicates that the impedance analysis associated with that trigger condition is performed.

Decision block 940 tests to see if there are more trigger conditions to monitor for within the current test sequence loop. If so, operation block 942 indicates that the next trigger condition is set and the process loops to begin monitoring for the next trigger condition.

Decision block 946 test to see if there are more test sequence loops to perform, of so, operation block 940 indicates that the first trigger for the next test sequence loop is set and the process loops to begin monitoring for the next trigger condition.

The IMB portable hardware components may be chosen such that they meet the particular requirements of the embedded electrochemical energy storage system to be measured. Additionally, the circuitry can be constructed for use with multiple DAQ system connections to allow for more flexibility in the measurement process (e.g., portable systems, DAQs with greater frequency ranges, etc.).

The impedance analysis system 100 may be configured for compact in-situ applications. In some embodiments, a protection circuit may be included to isolate the ESD 160 from the input signal when not in use. When triggered, the protection circuit initiates a pre-amp that activates an injection signal into the ESD and monitors the response through a data acquisition (DAQ) card. The data acquisition sends the necessary data back into the control software residing on a desktop computer, portable computer, or an embedded processor unit to calculate the impedance spectra. In this embodiment the combination of control using the DAQ performs functions similar to those discussed above for the switches 162 in FIG. 1.

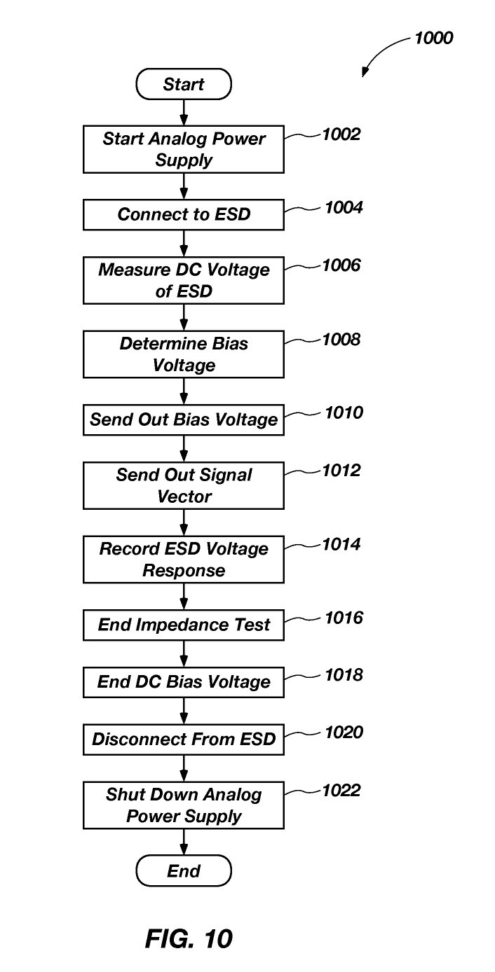

FIG. 10 is a simplified flow diagram 1000 of hardware control according to one or more embodiments of the present disclosure using the DAQ to IMB configuration. This operation may be more suitable for no-load conditions. Operation block 1002 indicates that the DAQ issues a signal to the IMB to power up the IMB analog power supply. Operation block 1004 indicates that the DAQ issues a signal to the IMB that will close the safety isolation switches and connect the 1 MB to the test ESD and thus enable the excitation signal to excite the ESD.

Operation block 1006 indicates that the DAQ performs a measurement of the ESD DC voltage just prior to the sending the excitation signal to the test ESD. Operation block 1008 indicates that the DAQ outputs a constant DC bias voltage to the IMB that is equal to an average of what the DAQ measured above. This bias voltage may be analog subtracted from the ESD voltage to enable a high-resolution detection of the ESD response to the excitation signal. Operation block 1010 indicates that the bias voltage is sent out by the DAQ.

Operation block 1012 indicates that the signal vector is sent to the IMB and, in turn, the IMB signal current to the ESD. This process initiates the stimulus signal to the test ESD. Operation block 1012 indicates that the analog voltage response from the ESD with the DAQ provided bias voltage subtracted off is sampled and digitized. Operation block 1014 indicates that the voltage response is recorded by the DAQ over the duration of the excitation signal.

Operation blocks 1016 and 1018 indicate the end of the impedance test and the DAQ ends the transmission of the stimulus signal and bias signal to the IMB and the excitation signal sent to the ESD ends. Operation block 1020 indicates that the DAQ directs the safety switches that connect the IMB to the ESD to open. Finally, operation block 1022 indicates that the DAQ disconnects the IMB power supply from its power source and, thus, shuts it down.

Table 2 lists the user interface features for an illustrative example of the present disclosure. An arrow pointing to the right indicates input by the user to the system and an arrow pointing to the left indicates input to the user by the system. All inputs have, as shown, default values that will change to what the user inputs. Those user inputs will be preserved until the program is closed and upon reopening will reset to the default values (except for calibration constants). When first started, a control dialog box opens (e.g., FIG. 4) and lets the user either “Run” or “Calibrate” the system. Table 3 gives the interface commands and signals between the DAQ and a Laptop via USB based on the illustrative example. The arrow to the right is from the Laptop to the DAQ and arrow to the left is from the DAQ to the Laptop.

TABLE 2
Portable IMB Software User Interface

| CONTROL (FIG. 4) | |
|---|---|
| RUN DIALOG | |
| Sample Freq | → |
| # Periods | → |

| | |
|---|---|
| Data Out File Name/Path | → |

| | |
|---|---|
| F_{lowest} | → |
| # Freq | → |
| Irms | → |
| Test Time | ← |
| # Samples | ← |
| F_{end} | ← |
| Run | → |

| | |
|---|---|
| Battery DC Voltage | ← |

| | |
|---|---|
| Done | ← |

| CALIBRATE DIALOG (FIG. 5) | |
|---|---|
| Low value shunt | ← |
| Middle value shunt | ← |
| Hi value shunt | ← |
| Magnitude A | ← |
| Magnitude B | ← |
| Phase A | ← |
| Phase B | ← |
| Calibrate | → |
| OK | → |
| Cancel | → |

| | |
|---|---|
| Hook up low value shunt | ← |
| Hook up middle value shunt | ← |
| Hook up high value shunt | ← |

TABLE 3
Portable IMB Laptop to DAQ USB Interface

Turn on/off power supply (Bi-level) →
Connect/disconnect to Battery (Bi-level) →
Battery Voltage (Analog) ←
Battery bias voltage (Analog) →
SOS to DAQ (Analog) →
Battery response (Analog) ←
DAQ sample frequency →
DAQ channel full scale range →

While the invention is susceptible to various modifications and implementation in alternative forms, specific embodiments have been shown by way of non-limiting examples in the drawings and have been described in detail herein. However, it should be understood that the invention is not intended to be limited to the particular forms disclosed. Rather, the invention includes all modifications, equivalents, and alternatives falling within the scope of the following appended claims and their legal equivalents.

1. An impedance analysis system for characterizing an energy storage device, comprising:
a signal vector assembler configured to generate a signal vector from a composition of one or more waveforms over a stimulus duration;
a signal generator configured for generating a stimulus signal responsive to the signal vector and for switchable coupling to an energy storage device;
a response measurement device operably coupled to the stimulus signal and configured for measuring a response signal indicative of a response of the energy storage device substantially simultaneously with when the stimulus signal is applied to the energy storage device;
a load variation monitor operably coupled to the energy storage device and configured for monitoring load variations on the energy storage device due to operational circuitry coupled thereto; and
an analyzer operably coupled to the response signal, the analyzer configured for analyzing the response signal relative to the signal vector to determine an impedance of the energy storage device.

2. The impedance analysis system of claim 1, wherein the load variation monitor comprises:
a current sensor operably coupled to the energy storage device; and
a trigger monitor operably coupled to the current sensor and configured for indicating at least one condition of interest responsive to the load variations on the energy storage device sensed by the current sensor, wherein an impedance analysis by the impedance analysis system is triggered responsive to the condition of interest.

3. The impedance analysis system of claim 2, wherein the current sensor comprises a resistor configured for operable coupling between the stimulus signal and the energy storage device to indicate the load variations as a voltage drop across the resistor.

4. The impedance analysis system of claim 2, wherein the trigger monitor is configured to indicate multiple conditions of interest including charging conditions, discharging conditions, and a combination thereof.

5. The impedance analysis system of claim 1, further comprising a calibration module operably coupled to the signal generator and the analyzer wherein the signal generator is configured for applying the stimulus signal to the calibration module and the analyzer is configured for analyzing a calibration response signal responsive to the signal vector being applied to the calibration module to determine a baseline operation of the impedance analysis system and wherein analyzing the calibration response signal comprises performing a same analysis as analyzing the response signal.

6. The impedance analysis system of claim 5, wherein the calibration module comprises a variable shunt operably coupled between the stimulus signal and the calibration response signal and is configured for selecting multiple impedance values for the variable shunt responsive to input from the analyzer.

7. The impedance analysis system of claim 5, further comprising one or more switches configured to connect and disconnect the calibration module from the stimulus signal and the analyzer.

8. The impedance analysis system of claim 1, wherein the analyzer is configured for:
periodically sampling the response signal over the stimulus duration;
correlating the sampled response to the signal vector; and
determining the impedance of the energy storage device responsive to the correlation.

9. The impedance analysis system of claim 1, wherein the signal generator is configured as a current generator or as a voltage generator.

10. The impedance analysis system of claim 1, wherein the response measurement device is configured as a current measurement device or as a voltage measurement device.

11. The impedance analysis system of claim 1, further comprising a bias reducer operably coupled to a bias signal and the response signal, the bias reducer configured for generating a bias-reduced response by substantially removing the bias signal from the response signal.

12. The impedance analysis system of claim 1, further comprising one or more switches configured to connect and disconnect the signal generator from the energy storage device.

13. The impedance analysis system of claim 1, wherein the response measurement device comprises a resistor configured for operable coupling between the stimulus signal and the energy storage device, wherein the response signal is correlated to a voltage drop across the resistor.

14. The impedance analysis system of claim 1, further comprising a computing system wherein the signal vector assembler and the analyzer are included in the computing system.

15. The impedance analysis system of claim 14, wherein the analyzer includes computer instructions, which when executed by the computing system, perform the process of:
periodically sampling the response signal to over the stimulus duration;
correlating the sampled response to the signal vector; and
determining the impedance of the energy storage device responsive to the correlation.

16. The impedance analysis system of claim 15, further comprising a display, and wherein the analyzer includes additional computer instructions, which when executed by the computing system, perform the process of displaying, on the display, at least one characteristic of interest related to the impedance of the energy storage device.

17. A method of analyzing an energy storage device, comprising:
sampling a direct current value of the energy storage device resulting from operational circuitry coupled thereto;
closing one or more switches after sampling the direct current value to operably couple an impedance analysis system to the energy storage device;
forming a signal vector for analysis of the energy storage device from a composition of one or more waveforms;
biasing the signal vector proportional to the direct current value; and
performing an impedance analysis by:
generating a stimulus signal correlated to the signal vector;
applying the stimulus signal to a terminal of the energy storage device;
sampling a response of the energy storage device to the stimulus signal over a sampling duration; and
analyzing the response of the energy storage device relative to the signal vector over the sampling duration to determine an impedance of the energy storage device.

18. The method of claim 17, further comprising opening the one or more switches after applying the stimulus signal to operably decouple the impedance analysis system from the energy storage device.

19. The method of claim 17, wherein the acts of sampling the direct current value, closing the one or more switches, forming the signal vector, biasing the signal vector, and performing the impedance analysis are performed in response to a user input.

20. The method of claim 17, further comprising:
monitoring load variations on the energy storage device resulting from the operational circuitry coupled thereto;
detecting a condition of interest from the load variations; and
performing the impedance analysis responsive to detecting the condition of interest.

21. The method of claim 20, further comprising detecting additional conditions of interest and repeating the performing the impedance analysis responsive to the additional conditions of interest.

22. The method of claim 20, wherein the condition of interest is selected from the group consisting of charging conditions, discharging conditions, and a combination thereof.

23. The method of claim 17, further comprising performing calibration for the analyzing the response of the energy storage device by:
selectively coupling a calibration module to the stimulus signal;
applying the stimulus signal to the calibration module;
sampling a calibration response signal of the calibration module responsive to the stimulus signal over the sampling duration; and
analyzing the calibration response signal relative to the stimulus signal over the sampling duration to determine a baseline operation.

24. The method of claim 23, wherein selectively coupling the calibration module to the stimulus signal comprises coupling a variable shunt between the stimulus signal and the calibration response signal and repeating the acts of applying the stimulus signal to the calibration module, sampling the calibration response signal, and analyzing the calibration response signal for different values for the variable shunt.

25. The method of claim 17, further comprising displaying, on a display, at least one characteristic of interest related to the impedance of the energy storage device.

26. A method of analyzing an energy storage device, comprising:
monitoring load variations on the energy storage device resulting from operational circuitry coupled thereto;
detecting a condition of interest from the load variations;
forming a signal vector for analysis of the energy storage device from a composition of one or more waveforms; and
performing an impedance analysis responsive to detecting the condition of interest, the impedance analysis comprising:
generating a stimulus signal correlated to the signal vector;
applying the stimulus signal to a terminal of the energy storage device;
sampling a response of the energy storage device to the stimulus signal over a sampling duration; and
analyzing the response of the energy storage device relative to the stimulus signal over the sampling duration to determine an impedance of the energy storage device.

27. The method of claim 26, further comprising detecting additional conditions of interest and repeating the performing the impedance analysis responsive to the additional conditions of interest.

28. The method of claim 26, wherein the condition of interest is selected from the group consisting of charging conditions, discharging conditions, and a combination thereof.

29. The method of claim 26, further comprising:
sampling a direct current value of the energy storage device from the operational circuitry coupled thereto;
closing one or more switches after sampling the direct current value to operably couple the stimulus signal to the energy storage device;
biasing the stimulus signal proportional to the direct current value; and
opening the one or more switches after applying the stimulus signal.

30. The method of claim 29, wherein the acts of sampling the direct current value, closing the one or more switches, forming the signal vector, biasing the stimulus signal, performing the impedance analysis, and opening the one or more switches are performed in response to a user input.

31. The method of claim 26, further comprising performing calibration for the analyzing the response of the energy storage device by:
selectively coupling a calibration module to the stimulus signal;
applying the stimulus signal to the calibration module;
sampling a calibration response signal of the calibration module responsive to the stimulus signal over the sampling duration; and
analyzing the calibration response signal relative to the stimulus signal over the sampling duration to determine a baseline operation.

32. The method of claim 31, wherein selectively coupling the calibration module to the stimulus signal comprises coupling a variable shunt between the stimulus signal and the calibration response signal and repeating the acts of applying the stimulus signal to the calibration module, sampling the calibration response signal, and analyzing the calibration response signal for different values for the variable shunt.

33. The method of claim 26, further comprising displaying, on a display, at least one characteristic of interest related to the impedance of the energy storage device.
